(19) United States
(12) Patent Application Publication
(10) Pub. No.: US 2015/0140798 A1
(43) Pub. Date: May 21, 2015

(54) SEMICONDUCTOR MANUFACTURING METHOD AND EQUIPMENT THEREOF

(71) Applicant: TAIWAN SEMICONDUCTOR MANUFACTURING COMPANY LTD., Hsinchu (TW)

(72) Inventor: FANG-YUE HSU, TAICHUNG CITY (TW)

(73) Assignee: TAIWAN SEMICONDUCTOR MANUFACTURING COMPANY LTD., Hsinchu (TW)

(21) Appl. No.: 14/080,880

(22) Filed: Nov. 15, 2013

(51) Int. Cl. H01L 21/677; C23C 16/458; H01L 29/51; C23C 16/52; H01L 21/02; H01L 21/673

(52) U.S. Cl. CPC H01L 21/67745; H01L 21/02172; H01L 21/0234; H01L 21/6732; H01L 29/517; C23C 16/52; C23C 16/4582
USPC 438/591; 438/798; 438/785; 118/697

(57) ABSTRACT

A semiconductor manufacturing equipment includes a buffer chamber, a load port, a first chamber, and a second chamber respectively connected with the buffer chamber at a different side. The semiconductor manufacturing equipment also has a third chamber in the buffer chamber, the third chamber configured for cooling a wafer, and a single blade robot in the buffer chamber. Moreover, the semiconductor manufacturing equipment has a controller including a program, wherein the program elevates a wafer transfer priority for the first chamber and the second chamber higher than a wafer transfer priority for the third chamber.

### FIELD

The disclosure relates to a semiconductor equipment and operation method thereof.

### BACKGROUND

The semiconductor integrated circuit (IC) industry has experienced rapid growth. As the dimensions of transistors decrease, the thickness of the gate oxide must be reduced to maintain performance with the decreased gate length. However, in order to reduce gate leakage, high dielectric constant (high-k) gate insulator layers are used which allow greater physical thicknesses while maintaining the same effective thickness as would be provided by a typical gate oxide used in larger technology nodes.

Additionally, as technology nodes shrink, in some IC designs, there has been a desire to replace the typically polysilicon gate electrode with a metal gate (MG) electrode to improve device performance with the decreased feature sizes. One process of forming the MG electrode is termed “gate last” process in which the final metal gate electrode is fabricated “last” which allows for reduced number of subsequent processes, including high temperature processing, that must be performed after formation of the gate.

However, problems arise when integrating a high-k/metal gate feature in a CMOS technology process flow due to various factors such as incompatibility of materials, complex processes, and thermal budgets. Therefore, for these advances to be realized, similar developments in IC processing and manufacturing are needed.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross sectional view of a semiconductor structure at a stage of high k metal gate formation process in accordance with some embodiments of the present disclosure.

FIG. 2 is a flow diagram of fabricating a semiconductor device with a high-k metal gate in accordance with some embodiments of the present disclosure.

FIG. 3 is a top view of semiconductor manufacturing equipment for fabricating a semiconductor device with a high-k metal gate in accordance with some embodiments of the present disclosure.

FIG. 4A is a top view of fabricating a wafer in the semiconductor manufacturing equipment of FIG. 3 in accordance with some embodiments of the present disclosure.

FIG. 4B is a top view of fabricating a wafer in the semiconductor manufacturing equipment of FIG. 3 at a surface treatment operation in accordance with some embodiments of the present disclosure.

FIG. 4C is a top view of fabricating a wafer in the semiconductor manufacturing equipment of FIG. 3 at annealing operation in accordance with some embodiments of the present disclosure.

FIG. 4D is a top view of fabricating a wafer in the semiconductor manufacturing equipment of FIG. 3 at cooling operation in accordance with some embodiments of the present disclosure.

FIG. 5A is a top view of fabricating a first wafer and a second wafer in the semiconductor manufacturing equipment of FIG. 3 at different operation stages in accordance with some embodiments of the present disclosure.

FIG. 5B is a top view of fabricating a first wafer and a second wafer in the semiconductor manufacturing equipment of FIG. 3 at different operation stages in accordance with some embodiments of the present disclosure.

FIG. 5C is a top view of fabricating a first wafer and a second wafer in the semiconductor manufacturing equipment of FIG. 3 at different operation stages with different transferring priority in accordance with some embodiments of the present disclosure

FIG. 6 is a flow diagram of fabricating a semiconductor device with a high-k metal gate with two independent SLSM in accordance with some embodiments of the present disclosure.

FIG. 7A is a top view of fabricating two first wafers in the semiconductor manufacturing equipment of FIG. 3 at different operation stages in accordance with some embodiments of the present disclosure.

FIG. 7B is a top view of fabricating two first wafers in the semiconductor manufacturing equipment of FIG. 3 at different operation stages in accordance with some embodiments of the present disclosure.

FIG. 7C is a top view of fabricating two first wafers and two second wafers continuously in the semiconductor manufacturing equipment of FIG. 3 at different operation stages in accordance with some embodiments of the present disclosure.

FIG. 7D is a top view of fabricating two first wafers and two second wafers continuously in the semiconductor manufacturing equipment of FIG. 3 at different operation stages in accordance with some embodiments of the present disclosure.

FIG. 7E is a top view of fabricating two first wafers and two second wafers continuously in the semiconductor manufacturing equipment of FIG. 3 at different operation stages in accordance with some embodiments of the present disclosure.

### DETAILED DESCRIPTION OF THE INVENTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention. It is to be understood that the following disclosure provides many different embodiments or examples for implementing different features of various embodiments. Specific examples of components and arrangements are described below to simplify the present disclosure. These are, of course, merely examples and are not intended to be limiting.

Further, it is understood that several processing steps and/or features of a device may be only briefly described. Also, additional processing steps and/or features can be added and certain of the following processing steps and/or features can be removed or changed while still implementing the claims. Thus, the following description should be understood to represent examples only, and are not intended to suggest that one or more steps or features is required.

In addition, the present disclosure may repeat reference numerals and/or letters in the various examples. This repetition is for the purpose of simplicity and clarity and does not in itself dictate a relationship between the various embodiments and/or configurations discussed.

In the present disclosure, a semiconductor manufacturing method is designed to define wafer process sequence in multi-chamber semiconductor manufacturing equipment. Wafers are processed following a designated path without delay with a predetermined priority arranged in the sequencer.

In some embodiments, the semiconductor manufacturing method is designed for a metal gate module. The semiconductor manufacturing method is implemented in a gate last process.

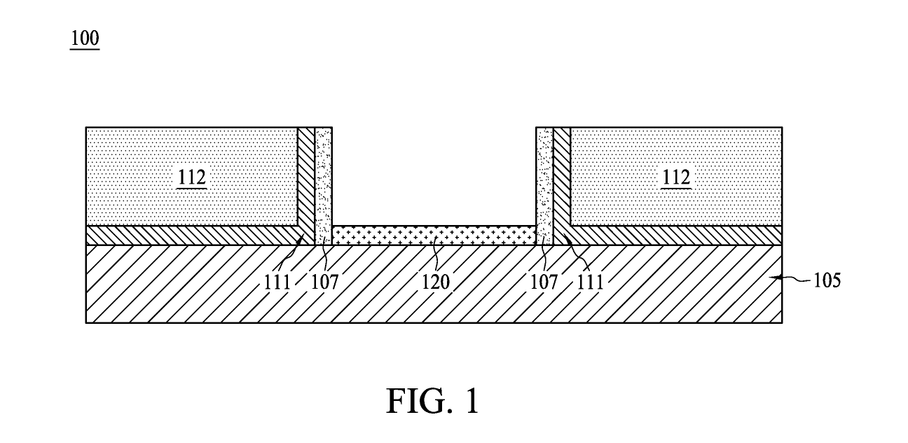

FIG. 1 is semiconductor structure 100 at a stage of high k metal gate formation process. The structure 100 has a substrate 105 and a high k dielectric 120 formed on the substrate 105. In some embodiments, the high-k dielectric layer 120 is formed by ALD, CVD, metalorganic CVD (MOCVD), PVD, plasma enhanced CVD (PECVD), plasma enhance ALD (PEALD), thermal oxidation, combinations thereof, or other suitable technique. In some embodiments, the high-k dielectric layer 120 includes a thickness ranging from about 5 to about 30 Å. The high-k dielectric layer 120 includes a binary or ternary high-k film such as HfOx. In some embodiments, the high-k dielectric layer 120 includes other high-k dielectrics such as LaO, AlO, ZrO, TiO, Ta2O5, Y2O3, SrTiO3 (STO), BaTiO3 (BTO), BaZrO, HfZrO, HfLaO, HfSiO, LaSiO, AlSiO, HfTaO, HfTiO, (Ba,Sr)TiO3 (BST), Al2O3, Si3N4, oxynitrides, or other suitable materials.

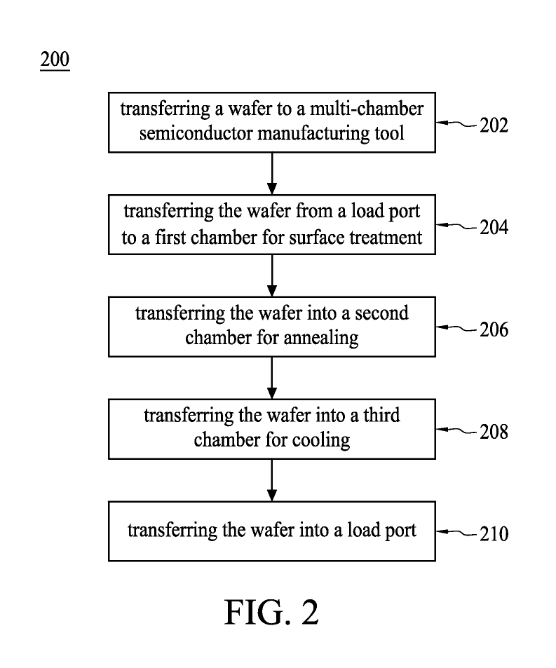

In some embodiments, a post high k dielectric deposition operation is implemented to adjust properties of the high k dielectric. FIG. 2 is a flow chart of a method 200 for fabricating a semiconductor device with a high-k metal gate according to various aspects of the present disclosure. The method 200 includes several operations and performed in a single semiconductor manufacturing tool. In operation 202, a wafer is loaded into a multi-chamber semiconductor manufacturing tool. In some embodiments, the multi-chamber semiconductor manufacturing tool includes at least two chambers and each chamber is designated for a different function or operation. In some embodiments, the multi-chamber semiconductor manufacturing tool includes at least two independent but identical lines. Each independent line includes at least two chambers and each chamber is designated for a different function or operation. A film like high k dielectric 120 in FIG. 1 is disposed on the wafer before the wafer is loaded into the multi-chamber semiconductor manufacturing tool. In some embodiments, a FOUP (Front Opening Unified Pod) having more than one wafer is loaded on the multi-chamber semiconductor manufacturing tool and the method 200 is performed for each wafer in a continuous manner. In operation 204, the wafer is transferred from a load port of the multi-chamber semiconductor manufacturing tool to a first chamber and the first chamber is configured for surface treatment on the high k dielectric. In some embodiments, the surface treatment is performed by a nitrogen plasma treatment. The nitrogen plasma treatment includes a nitrogen flow at between about 300 sccm and about 500 sccm. A radio frequency (RF) power between about 450 W and about 1600 W is applied on the first chamber. In some embodiments, the duration of surface treatment is between about 5 seconds and about 70 seconds. The pressure of surface treatment is between about 1.50 mTorr and about 2.2 mTorr.

In some embodiments, a pre heating operation is performed in the first chamber before starting the surface treatment operation. The pre heating is initiated prior to moving the wafer into the first chamber. The pre heating operation is performed at a temperature between about 850 degrees Celsius and about 900 degrees Celsius with a duration between about 25 seconds and about 40 seconds. In some embodiments, the pre heating operation takes about 30 seconds. In some embodiments, a diffusion operation is performed in the first chamber. The diffusion operation includes inserting impurities, such as donor type ions, into the high k dielectric in order to adjust the film property.

The method 200 continues with operation 206 in which the wafer is transferred into a second chamber after operation performed in the first chamber is accomplished. In some embodiments, operation 206 includes annealing the wafer by heating the wafer to a temperature between about 850 degrees Celsius and about 900 degrees Celsius. The annealing operation is under a pressure between about 4.5 Torr and about 5.0 Torr. In some embodiments, a duration of the annealing operation is between about 60 seconds and 100 seconds.

The method 200 continues with operation 208 after the annealing operation is accomplished in operation 206. In operation 208, the wafer is transferred from the second chamber to a third chamber for a cooling operation. In some embodiments, the wafer is cooled down in the third chamber for between about 120 seconds and about 200 seconds. In some embodiments, the wafer is cooled down in the third chamber for about 150 seconds.

The method 200 continues with operation 210 after the cooling operation is accomplished in operation 208. In operation 210, the wafer is transferred from the third chamber to a load port. In some embodiments, the load port is a load lock chamber and located in the multi-chamber semiconductor manufacturing tool.

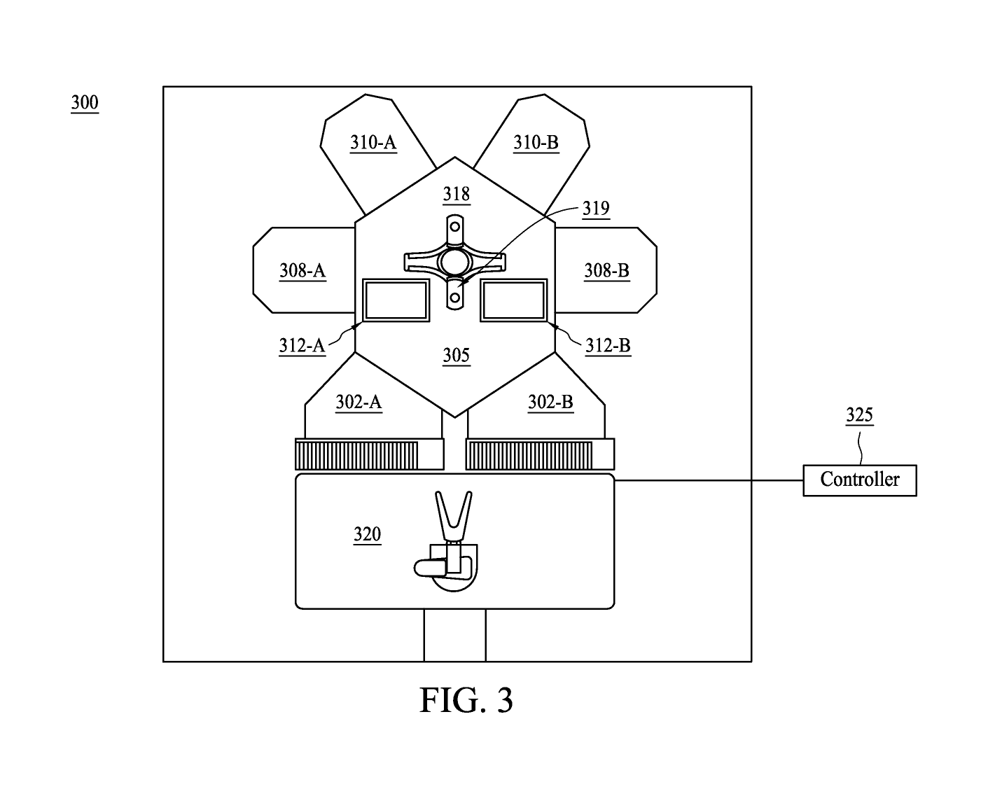

FIG. 3 is a semiconductor manufacturing equipment 300 for performing a post high k dielectric deposition operation. The semiconductor manufacturing equipment 300 includes two identical lines arranged symmetrically to a buffer chamber 305. Take the line left to the buffer chamber 305 (called A-line hereinafter) as an example, each line has a first chamber 308-A, connected with the buffer chamber 305 on a first side. A slit door for wafer transferring is at an interface between the first chamber 308-A and the buffer chamber 305. A second chamber 310-A is connected with the buffer chamber 305 on a second side and a slit door is at an interface between the second chamber 310-A and the buffer chamber 305. A third chamber 312-A is located in the buffer chamber 305. The third chamber 312-A is located close to the first chamber 308-A. A load port 302-A is connected with the buffer chamber 305 on a third side and a slit door is at an interface between the load port 302-A and the buffer chamber 305. The load port 302-A is further connected with an interface 320 and the interface 320 is designed to receive a wafer transferred from a FOUP (not shown in the drawing).

The other line (called B-line hereinafter) includes chambers 302-B, 308-B, 310-B, and 312-B that are identical to the configuration in A-line. A single blade robot 318 is in the buffer chamber 305. The single blade robot 318 is configured to relocate wafer between chambers or load port. In some embodiments, A-line and B-line share a common single blade robot 318.

The semiconductor manufacturing equipment 300 further includes a controller 325. In some embodiments, the controller 325 is remote from the semiconductor manufacturing equipment 300 and thereby a wire is added to build a connection between the controller 325 and the semiconductor manufacturing equipment 300. The controller 325 has a program (not shown) designed to perform a sequencer (not shown). The sequencer controls the sequence of wafer movement in semiconductor manufacturing equipment 300. Each wafer is assigned a sequence of process by the sequencer. In some embodiments, the program determines wafer movement priority in semiconductor manufacturing equipment 300. In some embodiments, the program elevates wafer transfer priority for the first chamber 308-A/B and the second chamber 310-A/B to be higher than the priority for the third chamber 312-A/B.

A wafer transferred in semiconductor manufacturing equipment 300 is assigned to be processed in either A-line or B-line. If a wafer is assigned to be processed in A-line, the wafer follows the assigned sequence that starts from load port 302-A, first chamber 308-A, second chamber 310-A, third chamber 312-A, and then back to load port 302-A. Each wafer follows the same order of without interchangeability. Moreover, the wafer assigned to be processed in A-line is not allowed to be transferred into any chamber or load port in B-line. The manner of wafer sequence arrangement is called single line serial mode (SLSM) in the present disclosure.

In some embodiments, first chamber 308-A or 308-B is configured for performing surface treatment on a wafer after high k dielectric deposition in metal gate module; second chamber 310-A or 310-B is configured for performing wafer annealing. Third chamber 312-A or 312-B is configured for performing wafer cooling.

In the following embodiments, process parameters such as temperature, power, duration of pre heating, surface treatment, annealing, and cooling, are referred to detailed description associated with method 200.

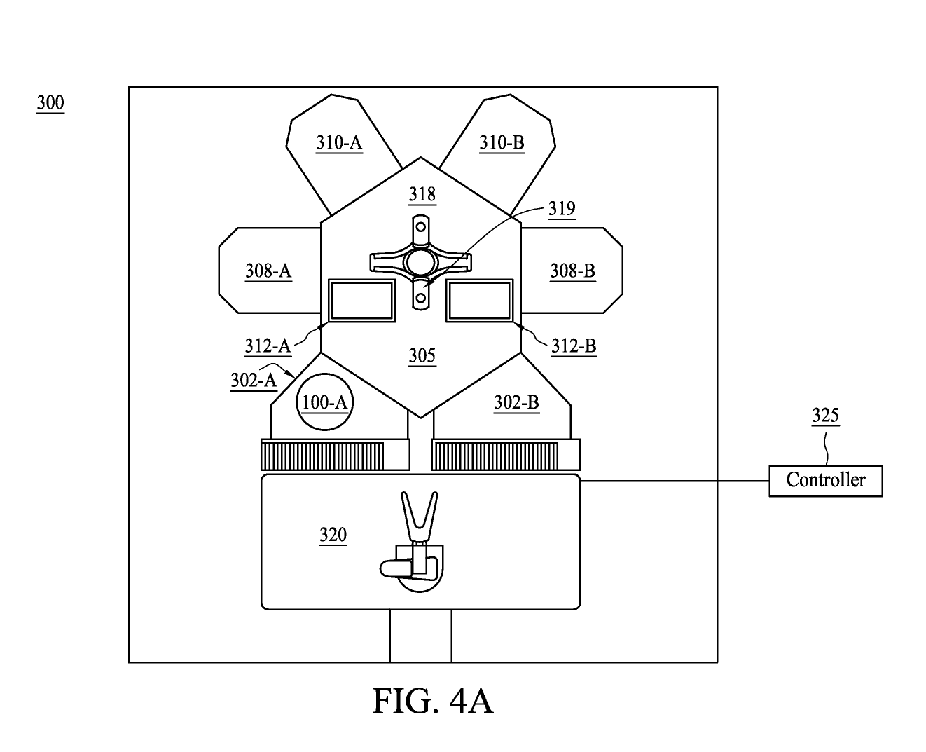

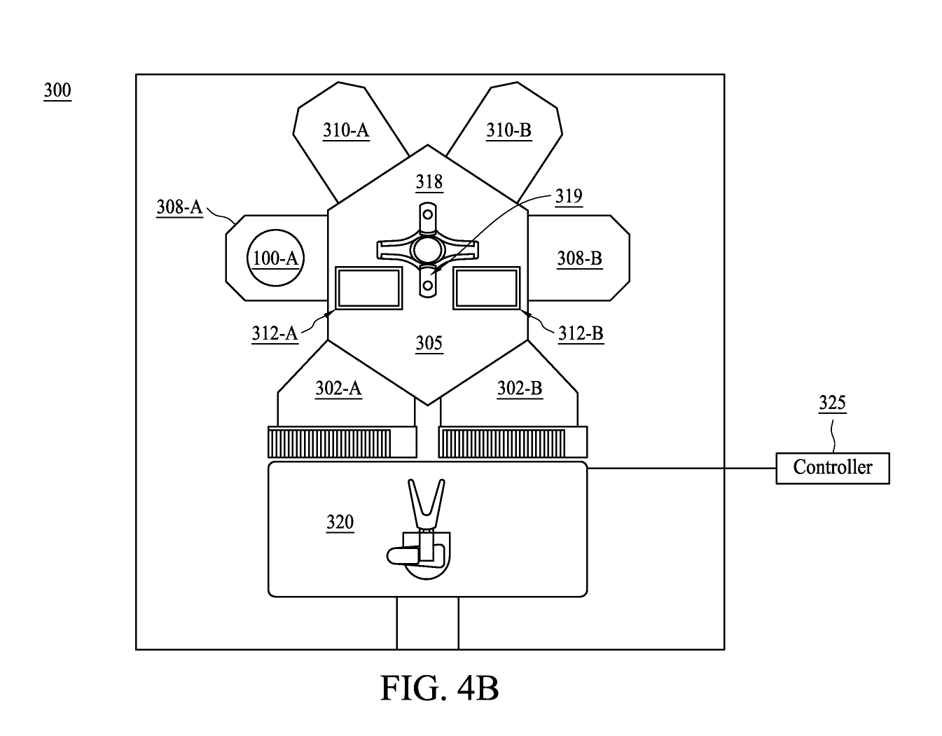

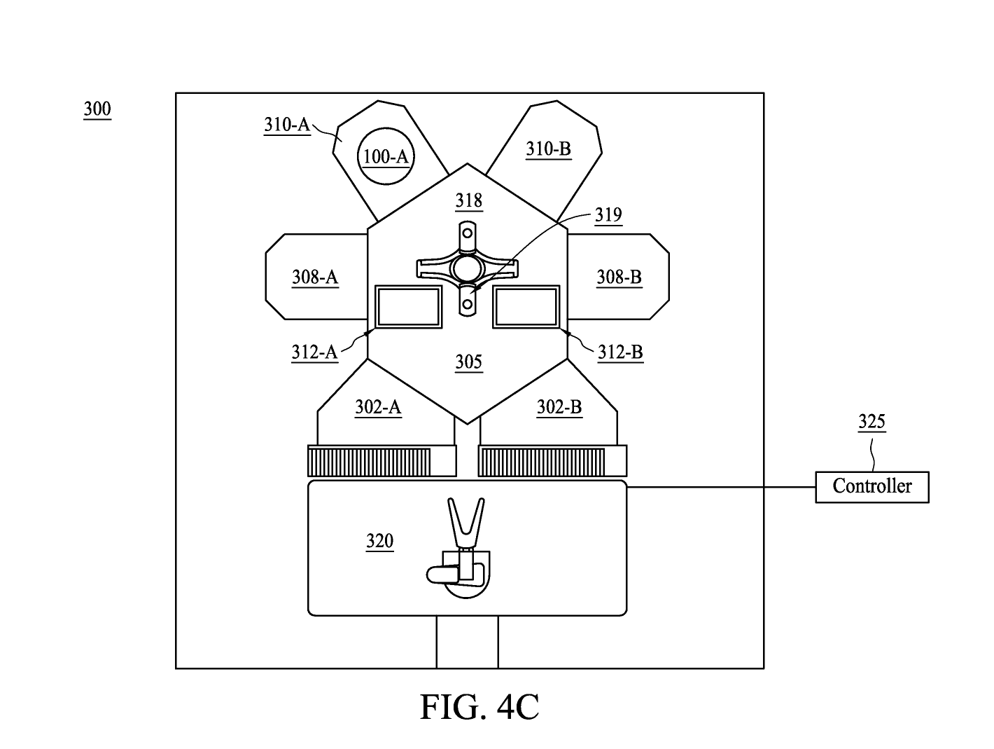

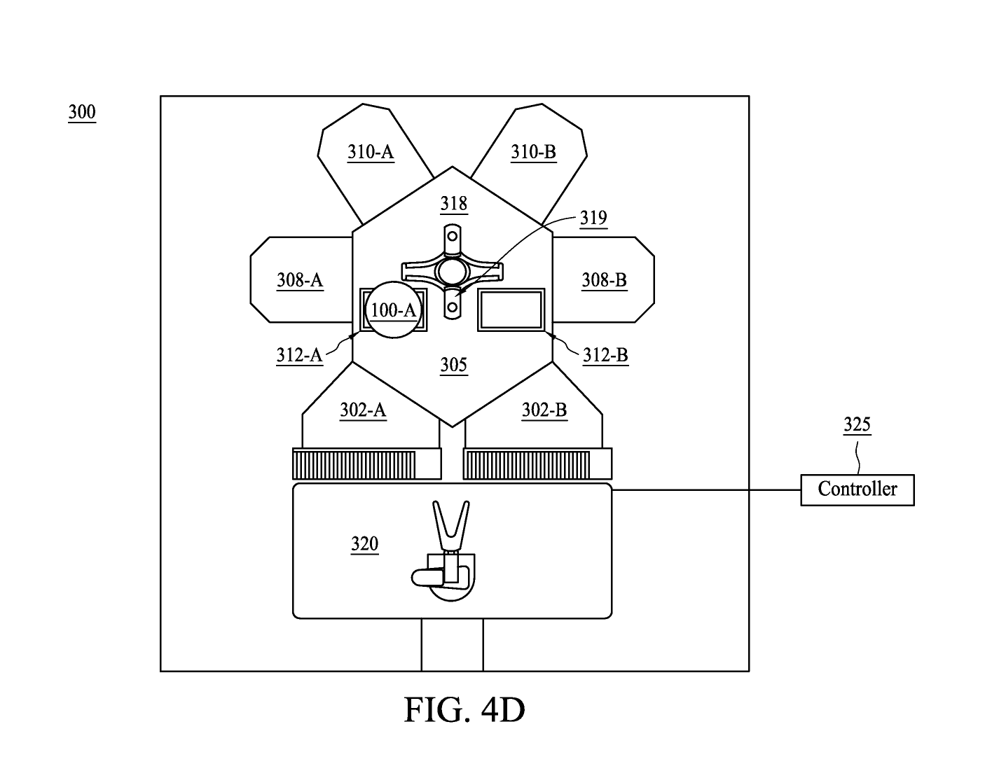

FIG. 4A is an operation of a semiconductor manufacturing method in accordance with some embodiments of the present disclosure. A first wafer 100-A is loaded into first load port 302-A. The first load port 302-A is pumped down from atmospheric (around 1 atm) to vacuum after receiving the first wafer 100-A. In some embodiments, first load port 302-A is pumped down to a pressure that is substantially same with buffer chamber 305. A pre heating operation is initiated in first chamber 308-A while the first wafer 100-A is in first load port 302-A. In some embodiments, the pre heating operation takes about 30 seconds. When the pre heating operation is accomplished, first wafer 100-A is transferred by robot blade 319 and moved into first chamber 308-A as shown in FIG. 4B. Plasma is generated in first chamber 308-A to treat a top surface of the first wafer 100-A for a duration. In some embodiments, there is an additional step of inserting impurities into the first wafer 100-A in the first chamber 308-A. The impurities are donor type ions.

The method continues and the first wafer 100-A is transferred into second chamber 310-A by robot blade 319 after the surface treatment on the first wafer 100-A is accomplished in first chamber 308-A. As in FIG. 4C, wafer 100-A stays in second chamber 310-A and receives an annealing to stabilize surface condition of first wafer 100-A. The first wafer 100-A is elevated to a high temperature after annealing.

In some embodiments, there is control to reduce first wafer 100-A idle time in the first chamber 308-A after surface treatment. The first wafer 100-A is not allowed to stay in the first chamber 308-A over a predetermined period after surface treatment. In some embodiments, the period is between about 10 seconds and 20 seconds. In some embodiments, the period is about 15 seconds.

The first wafer 100-A is further transferred into a third chamber 312-A after the annealing operation is accomplished in the second chamber 310-A. As in FIG. 4D, the first wafer 100-A is picked from the second chamber 310-A by the robot blade 319 and moved into the third chamber 312-A. The first wafer 100-A is cooled down in the third chamber 312-A. The first wafer 100-A is transferred into first load port 302-A by the robot blade 319 after the first wafer 100-A is cooled down to a predetermined temperature.

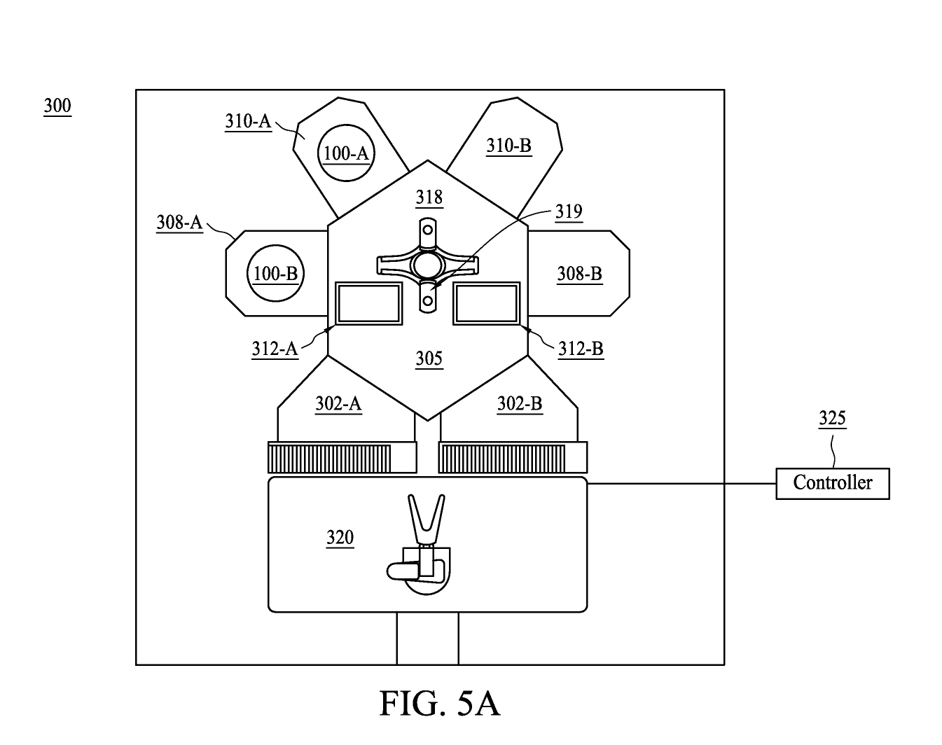

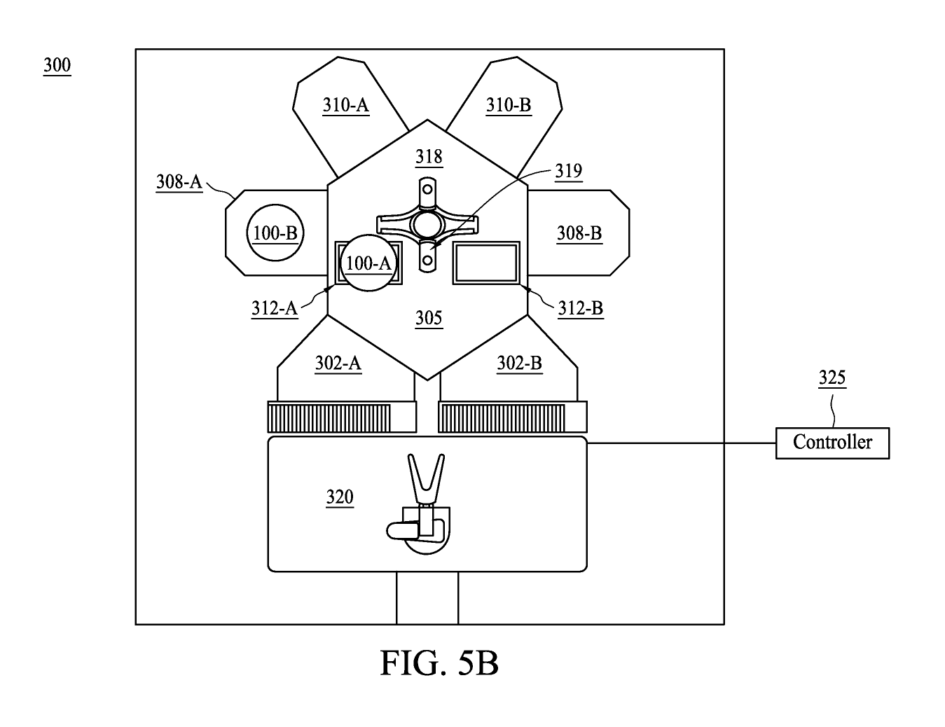

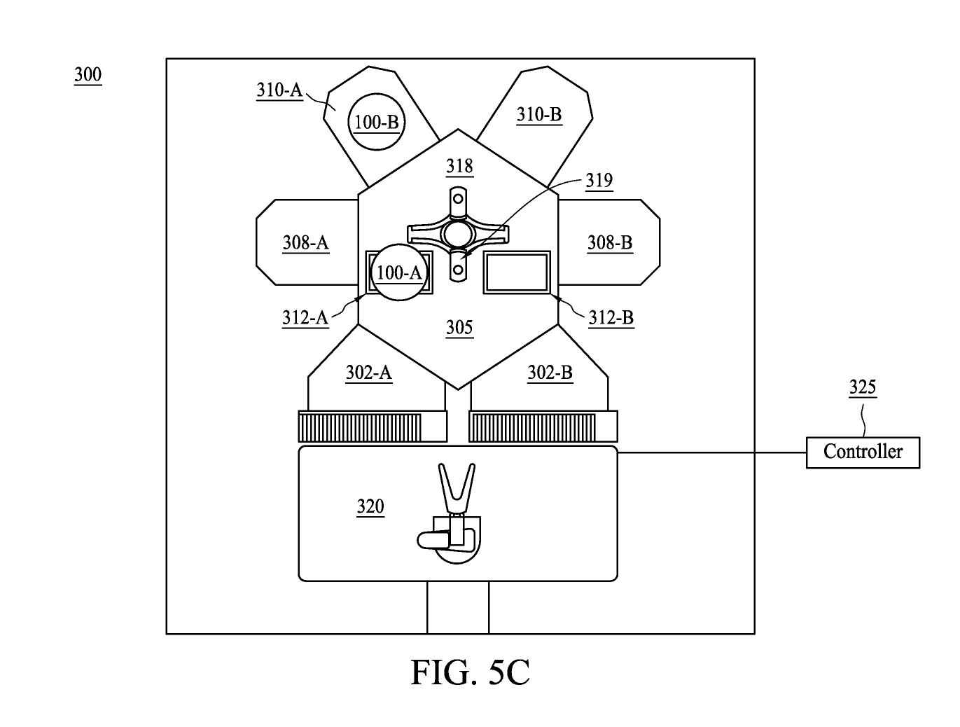

In some embodiments, there is a second wafer 100-B under a same sequence like the first wafer 100-A. As in FIG. 5A, a second wafer 100-B is transferred into first chamber 308-A for surface treatment after the first wafer 100-A is moved into second chamber 310-A for annealing. The surface treatment operation performed on the first wafer 100-A in the first chamber 308-A has a duration T₁, and the annealing operation performed on the second wafer 100-B in the second chamber 308-B has a duration T₂.

In some embodiments, when T₁ is greater than T₂, the first wafer 100-A is transferred into the third chamber 312-A for cooling before the surface treatment on the second wafer 100-A is accomplished. The cooling operation has duration T₃, which is greater than T₁-T₂₅ in other words, surface treatment on the second wafer 100-B is accomplished before the cooling operation on the first wafer 100-A is accomplished. In order to prevent the second wafer 100-B from staying in the first chamber 308-A over the predetermined period after surface treatment, the controller 325 orders the sequencer to request robot blade 319 picking the second wafer 100-B from the first chamber 308-A and moving the second wafer 100-B into the second chamber 310-A. The robot blade 319 is not allowed to move the first wafer 100-A from the third chamber only when there is no wafer idling in the first chamber 308-A. The wafer transferring sequence in which from first chamber 308-A to second chamber 310-A has a higher priority than transferring the first wafer 308-A from third chamber 312-A into load port 302-A.

In some embodiments, a metallic material is further deposited on the first wafer 100-A in another tool after the cooling operation in third chamber 312-A is accomplished. A barrier layer is formed over the high k dielectric layer 120 in FIG. 1. The barrier layer includes TiN or TaN having a thickness ranging from about 5 to about 30 Å. The barrier layer functions as a barrier to protect the high-k dielectric layer 120. The barrier layer is formed by various deposition techniques such as ALD, PVD, CVD, PECVD, or other suitable technique.

In some embodiments, a metal layer is formed to cover the barrier layer. The metal layer includes any metal material suitable for forming a metal gate or portion thereof, including work function layers, liner layers, interface layers, seed layers, adhesion layers, barrier layers, etc. For example, a P-type work function metal (P-metal) may be formed over the barrier layer. The P-metal layer may be formed by ALD, PVD, CVD, or other suitable process. Alternatively, the P-metal layer includes other suitable metals, such as WN, TaN, or Ru, that properly perform in the PFET (P-type Field Effective Transistor) device. In some embodiments, the P-metal layer includes a multi-metal layer structure such as TiN/WN.

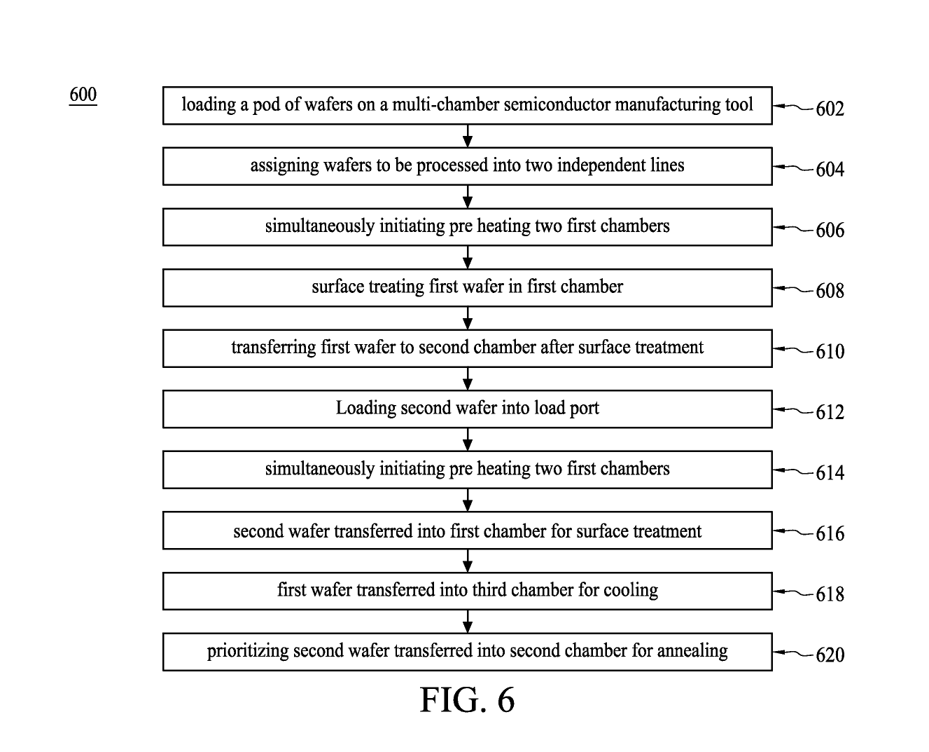

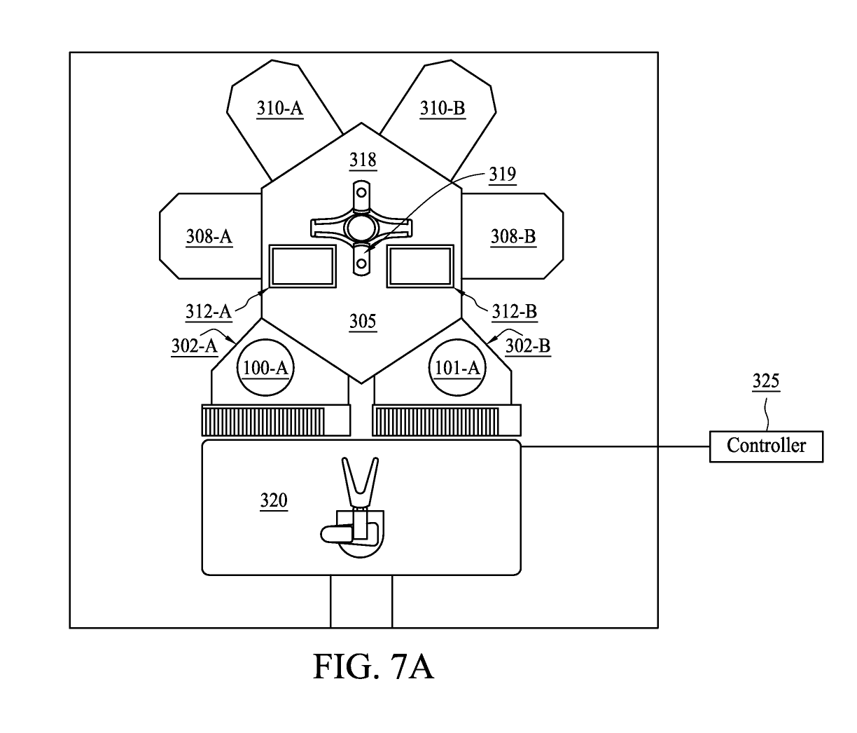

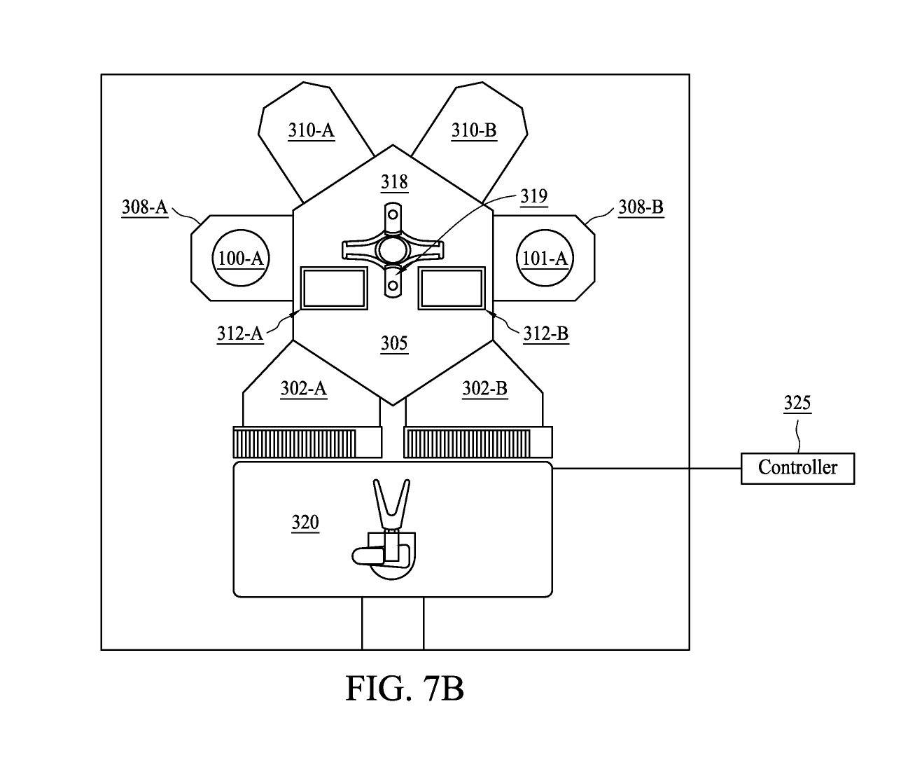

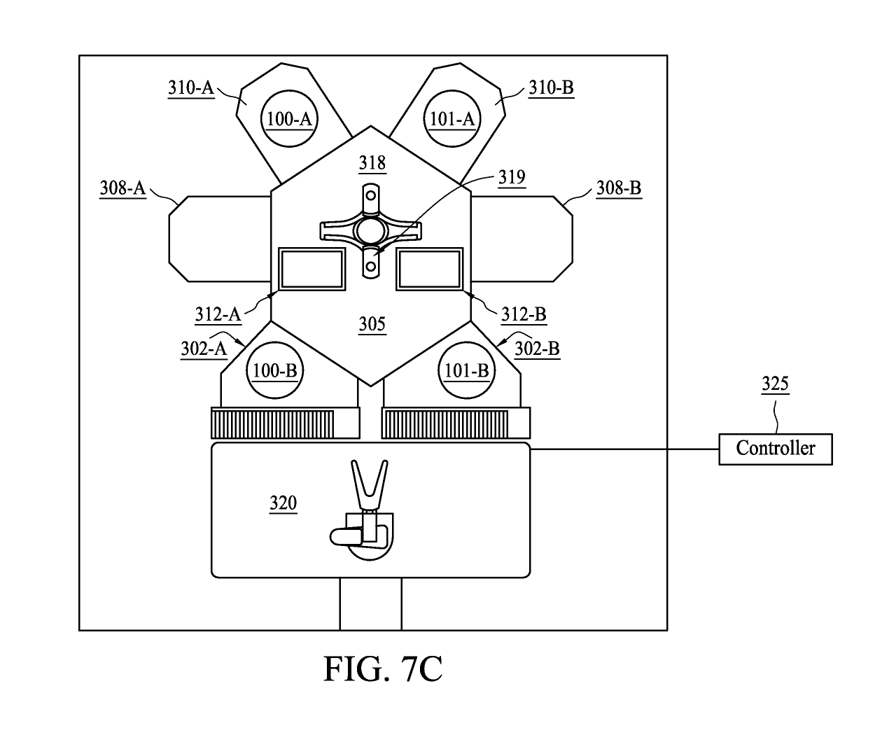

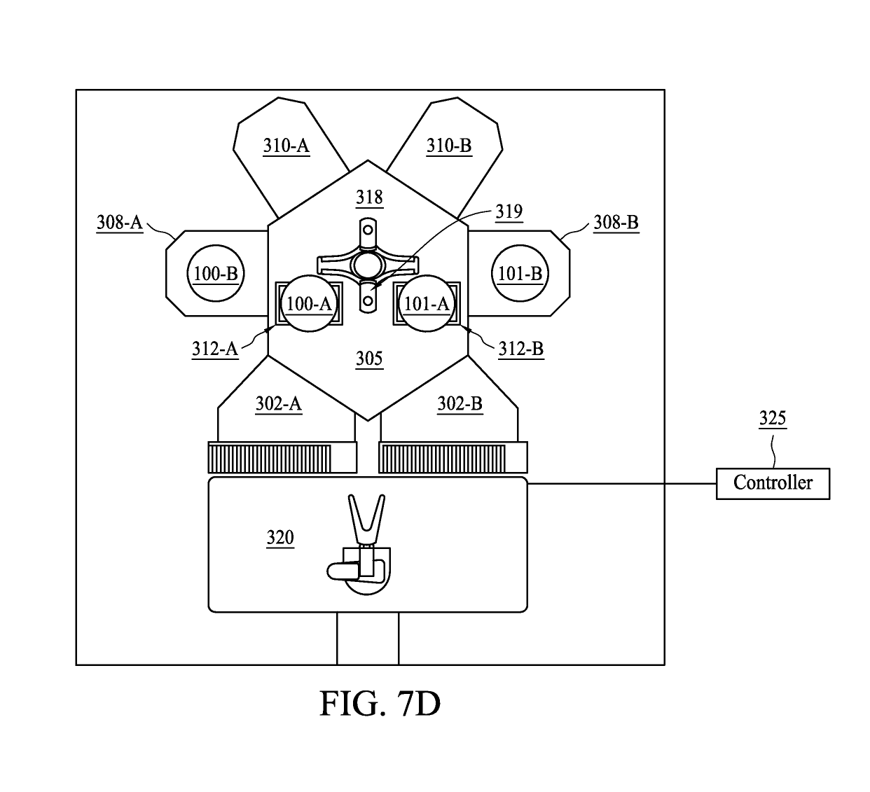

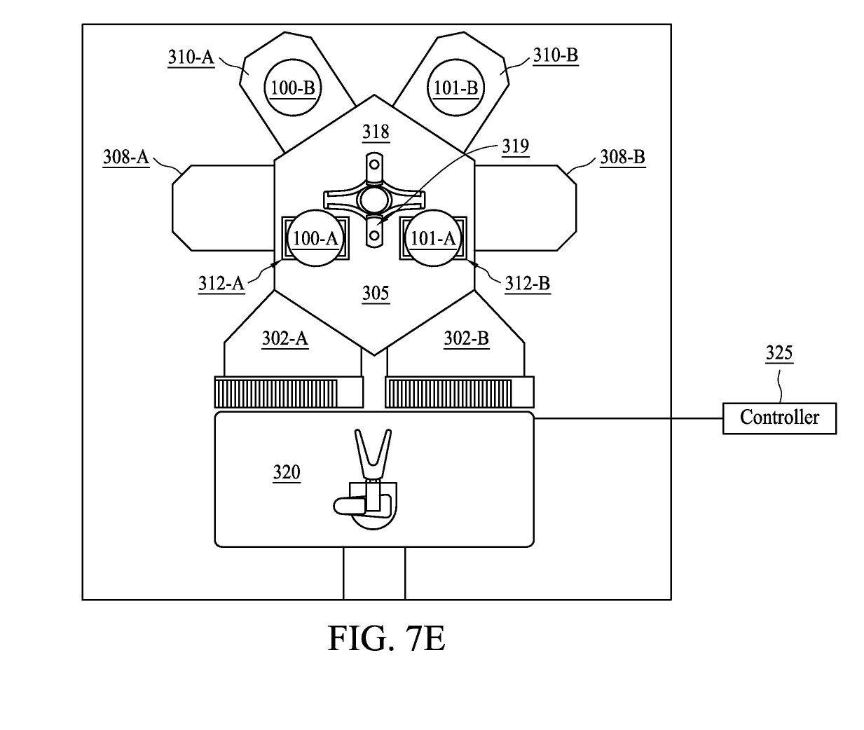

FIG. 6 is a flow chart of a method 600 for fabricating a semiconductor device with a high-k metal gate according to various aspects of the present disclosure. The method 600 includes several operations. In operation 602, a pod including several semiconductor wafers is loaded on a multi-chamber semiconductor manufacturing tool. In some embodiments, the multi-chamber semiconductor manufacturing tool is referred to FIG. 3. In operation 604, wafers in the pod are assigned to be processed in two independent lines. In some embodiments, wafers are processed parallel in a single line serial mode (SLSM). As in FIG. 7A, first wafers 100-A and 101-A are assigned to load port 302-A and 302-B respectively. Each wafer is also assigned with a sequence including operations 204 to 210 as in FIG. 2.

In operation 606, first chambers (308-A and 308-B) of each independent line are pre heated simultaneously. First wafers 100-A and wafer 101-A stay in load port until pre heat operation in each first chamber is accomplished, and then transferred by the robot blade 319 into a corresponding first chamber as in FIG. 7B. The pre heating duration for both chambers is identical, so that pre heating operation almost ends in same time for both chambers. In some embodiments, first wafer 100-A is picked from load port 302-A, and first wafer 101-A is picked from load port 302-B right after first wafer 100-A is transferred into first chamber 308-A. Both wafers are transferred to a corresponding first chamber to receive surface treatment. Surface treatment is initiated once the first chamber receives a wafer transferred from load port. Surface treatment on first wafer 100-A is initiated prior to surface treatment on first wafer 101-A. According to parallel SLSM performed in method 600, first wafer 101-A lags behind first wafer 100-A, but the difference is minimized to be the transfer time of first wafer 100-A moving from load port 302-A to first chamber 308-A.

In operation 608, each first wafer receives surface treatment in a corresponding first chamber. In operation 610, first wafers 100-A and 101-A are transferred into second chambers by the robot blade 319 for annealing. The method 600 continues with operation 612 and start loading second wafers 100-B and 101-B into their corresponding load port as in FIG. 7C. In operation 614, pre heating is initiated in each first chamber simultaneously as in operation 606.

In operation 616, each second wafer is transferred into a corresponding first chamber for surface treatment. In operation 618, each first wafer is transferred into a corresponding third chamber for cooling. Location of each wafer at operation 618 is illustrated in FIG. 7D.

In some embodiments, the cooling duration for the first wafer is greater than surface treatment duration for the second wafer. In operation 620, the controller 325 elevates the priority of transferring the second wafer into the second chamber to be higher than the priority of transferring the first wafer from third chamber to the load port as in FIG. 7E. Second wafers 100-B and 101-B are transferred into a corresponding second chamber before transferring first wafers 100-A and 101-A from third chamber to load port.

In some embodiments, there are more wafers loaded in serial after the second wafer and also follow the same sequence as in the above mentioned embodiments either in single SLSM or parallel SLSM.

In some embodiments, there are more than two independent lines designed in a semiconductor manufacturing tool. A method similar to method 600 is expanded to be adapted to more than two independent lines.

A semiconductor manufacturing method includes several operations. One of the operations is transferring a first wafer into a first chamber. One of the operations is surface treating the first wafer in the first chamber for a first duration. One of the operations is transferring the first wafer into a second chamber after the surface treating the first wafer in the first chamber being accomplished. One of the operations is annealing the first wafer in the second chamber for a second duration. One of the operations is transferring the first wafer from the second chamber into a third chamber after the annealing the first wafer in the second chamber being accomplished. One of the operations is cooling the first wafer in the third chamber for a third duration. One of the operations is transferring the first wafer into a load port after the cooling the first wafer in the third chamber being accomplished. One of the operations is transferring a second wafer into the first chamber. One of the operations is surface treating the second wafer in the first chamber for the first duration. One of the operations is transferring the second wafer into the second chamber after the surface treating the second wafer in the first chamber being accomplished. The transferring the second wafer into the second chamber after the surface treating the second wafer in the first chamber being accomplished is performed with a higher priority than the transferring the first wafer into a load port after the cooling the first wafer in the third chamber being accomplished.

In some embodiments, the semiconductor manufacturing method is performed with a single blade robot in a single semiconductor manufacturing equipment.

In some embodiments, the semiconductor manufacturing method further includes depositing a high k dielectric material on the first wafer prior to transferring the first wafer into the first chamber.

In some embodiments, the semiconductor manufacturing method further includes depositing a metallic material on the first wafer after the transferring the first wafer into the load port after the cooling the first wafer in the third chamber being accomplished.

In some embodiments, the semiconductor manufacturing method further includes inserting impurity on the first wafer in the first chamber.

In some embodiments, the surface treating the first wafer in the first chamber includes a nitrogen treatment. In some embodiments, the surface treating the first wafer in the first chamber includes a power between about 450 W and about 1600 W.

In some embodiments, the second duration is between about 60 and about 100 seconds.

In some embodiments, the third duration is around 150 seconds.

In some embodiments, the method further includes pumping down the load port from atmosphere to vacuum.

A semiconductor manufacturing method includes various operations. One of the operations is performing a post high k value dielectric deposition operation on a plurality of wafers with at least two independent lines. Each of the at least two independent lines includes several operations that has transferring a wafer into a first chamber; surface treating the wafer in the first chamber with a first duration; transferring the wafer into a second chamber after the first chamber accomplishing the surface treating the wafer; annealing the wafer in the second chamber with a second duration; transferring the wafer from the second chamber into a third chamber after accomplishing the annealing the wafer; cooling the wafer in the third chamber with a third duration; and transferring the wafer into a load port after accomplishing the cooling the wafer.

A semiconductor manufacturing method includes an operation of simultaneously heating the first chamber in each of the at least two independent lines before transferring a wafer into the first chamber.

In some embodiments, the simultaneously heating the first chamber includes a duration of about 30 seconds.

In some embodiments, the method further includes performing the post high k value dielectric deposition operation for at least two wafers in each of the at least two independent lines.

In some embodiments, the method further includes configuring in each of the at least two independent lines whether the surface treating the wafer in the first chamber is accomplished before the cooling the wafer in the third chamber is accomplished.

In some embodiments, the first chamber is a nitrogen treatment chamber.

In some embodiments, the annealing the wafer in the second chamber is under a pressure between about 4.5 Torr and about 5.0 Torr.

In some embodiments, the surface treating the wafer in the first chamber is under a pressure between about 1.50 mTorr and about 2.2 mTorr.

A semiconductor manufacturing equipment includes a buffer chamber, a load port, a first chamber, and a second chamber respectively connected with the buffer chamber at a different side. The semiconductor manufacturing equipment also has a third chamber in the buffer chamber, the third chamber configured for cooling a wafer, and a single blade robot in the buffer chamber. Moreover, the semiconductor manufacturing equipment has a controller including a program, wherein the program elevates a wafer transfer priority for the first chamber and the second chamber higher than a wafer transfer priority for the third chamber.

In some embodiments, the first chamber is configured for surface treating the wafer.

In some embodiments, the second chamber is configured for annealing the wafer.

Moreover, the scope of the present application is not intended to be limited to the particular embodiments of the process, machine, manufacture, and composition of matter, means, methods and steps described in the specification. As those skilled in the art will readily appreciate form the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure.

Accordingly, the appended claims are intended to include within their scope such as processes, machines, manufacture, and compositions of matter, means, methods or steps. In addition, each claim constitutes a separate embodiment, and the combination of various claims and embodiments are within the scope of the invention.

What is claimed is:

1. A semiconductor manufacturing method, comprising:
transferring a first wafer into a first chamber;
surface treating the first wafer in the first chamber for a first duration;
transferring the first wafer into a second chamber after the surface treating the first wafer in the first chamber being accomplished;
annealing the first wafer in the second chamber for a second duration;
transferring the first wafer from the second chamber into a third chamber after the annealing the first wafer in the second chamber being accomplished;
cooling the first wafer in the third chamber for a third duration;
transferring the first wafer into a load port after the cooling the first wafer in the third chamber being accomplished;
transferring a second wafer into the first chamber;
surface treating the second wafer in the first chamber for the first duration; and
transferring the second wafer into the second chamber after the surface treating the second wafer in the first chamber being accomplished;
wherein the transferring the second wafer into the second chamber after the surface treating the second wafer in the first chamber being accomplished is performed with a higher priority than the transferring the first wafer into a load port after the cooling the first wafer in the third chamber being accomplished.

2. The method of claim 1, wherein the semiconductor manufacturing method is performed with a single blade robot in a single semiconductor manufacturing equipment.

3. The method of claim 1, further comprising depositing a high k dielectric material on the first wafer prior to transferring the first wafer into the first chamber.

4. The method of claim 1, further comprising depositing a metallic material on the first wafer after the transferring the first wafer into the load port after the cooling the first wafer in the third chamber being accomplished.

5. The method of claim 1, further comprising inserting impurity on the first wafer in the first chamber.

6. The method of claim 1, wherein the surface treating the first wafer in the first chamber includes a nitrogen treatment.

7. The method of claim 1, wherein the surface treating the first wafer in the first chamber includes a power between about 450 W and about 1600 W.

8. The method of claim 1, wherein the second duration is between about 60 and about 100 seconds.

9. The method of claim 1, wherein the third duration is around 150 seconds.

10. The method of claim 1, further comprising pumping down the load port from atmosphere to vacuum.

11. A semiconductor manufacturing method, comprising:
performing a post high k value dielectric deposition operation on a plurality of wafers with at least two independent lines, wherein each of the at least two independent lines includes:
transferring a wafer into a first chamber;
surface treating the wafer in the first chamber with a first duration;
transferring the wafer into a second chamber after the first chamber accomplishing the surface treating the wafer;
annealing the wafer in the second chamber with a second duration;
transferring the wafer from the second chamber into a third chamber after accomplishing the annealing the wafer;
cooling the wafer in the third chamber with a third duration; and
transferring the wafer into a load port after accomplishing the cooling the wafer;
simultaneously heating the first chamber in each of the at least two independent lines before transferring a wafer into the first chamber.

12. The method of claim 11, wherein the simultaneously heating the first chamber includes a duration of about 30 seconds.

13. The method of claim 11, further comprising performing the post high k value dielectric deposition operation for at least two wafers in each of the at least two independent lines.

14. The method of claim 11, further comprising configuring in each of the at least two independent lines whether the surface treating the wafer in the first chamber is accomplished before the cooling the wafer in the third chamber is accomplished.

15. The method of claim 11, wherein the first chamber is a nitrogen treatment chamber.

16. The method of claim 11, wherein the annealing the wafer in the second chamber is under a pressure between about 4.5 Torr and about 5.0 Torr.

17. The method of claim 11, wherein the surface treating the wafer in the first chamber is under a pressure between about 1.50 mTorr and about 2.2 mTorr.

18. A semiconductor manufacturing equipment, comprising:
a buffer chamber;
a load port, a first chamber, and a second chamber respectively connected with the buffer chamber at a different side;
a third chamber in the buffer chamber, the third chamber configured for cooling a wafer;
a single blade robot in the buffer chamber; and,
a controller including a program, wherein the program elevates a wafer transfer priority for the first chamber and the second chamber higher than a wafer transfer priority for the third chamber.

19. The semiconductor equipment of claim 18, wherein the first chamber is configured for surface treating the wafer.

20. The semiconductor equipment of claim 18, wherein the second chamber is configured for annealing the wafer.
